(19) United States
(12) Patent Application Publication
(10) Pub. No.: US 2024/0375882 A1
(43) Pub. Date: Nov. 14, 2024

(54) Article Transport Facility

(71) Applicant: Daifuku Co., Ltd., Osaka-shi (JP)

(72) Inventors: Yuya Hirao, Hinocho (JP); Daisuke Ogawa, Hinocho (JP); Kosuke Sakamoto, Hinocho (JP)

(21) Appl. No.: 18/660,443

(22) Filed: May 10, 2024

(30) Foreign Application Priority Data
May 11, 2023 (JP) 2023-078831

(51) Int. Cl. B65G 43/00; B65G 1/04

(52) U.S. Cl. CPC B65G 43/00; B65G 1/0457

(57) ABSTRACT

An article transport facility includes a transport vehicle and a control device. The control device and the transport vehicle are configured to be communicable with each other in both directions via any of a plurality of access points. The control device transmits a command for communication recovery to the transport vehicle, as communication from the control device to the transport vehicle is valid, when communication from the transport vehicle to the control device is interrupted.

### CROSS-REFERENCE TO RELATED APPLICATION

This application claims priority to Japanese Patent Application No. 2023-078831 filed May 11, 2023, the disclosure of which is hereby incorporated by reference in its entirety.

### BACKGROUND OF THE INVENTION

### 1. Field of the Invention

The present invention relates to an article transport facility including a transport vehicle configured to move along a prescribed path to transport an article, a control device configured to control the transport vehicle, and a plurality of access points, each of which configured to perform wireless communication with the transport vehicle.

### 2. Description of Related Art

An example of such an article transport facility is disclosed in Japanese Patent Application Laid-Open No. 2011-166671. In the following, reference numerals shown in parentheses in the description of the related art are those of Japanese Patent Application Laid-Open No. 2011-166671.

In the facility disclosed in Japanese Patent Application Laid-Open No. 2011-166671, control devices (18 and 20) such as servers and a plurality of transport vehicles (12) are configured to be connected to each other via a wireless LAN to communicate with each other. Accordingly, the control devices (18 and 20) are able to ascertain a current position of the transport vehicle (12) or give a command such as a transport command to the transport vehicle (12) by wireless communication.

In the facility disclosed in Japanese Patent Application Laid-Open No. 2011-166671, since wireless communication is used for communication between the control devices (18 and 20) and the transport vehicle (12), communication failure may occur due to an abnormality of the communication device, the surrounding environment, or the like. The cause of the communication failure is not always specified, but in a case in which the communication failure occurs, it is preferable to take some measure to improve the communication state.

### SUMMARY OF THE INVENTION

In view of the above circumstances, there is a demand for realizing an article transport facility capable of favorably maintaining a communication state between a control device and a transport vehicle.

Techniques for solving the above problems are as follows.

An article transport facility including a transport vehicle configured to move along a prescribed path to transport an article; a control device configured to control the transport vehicle; and a plurality of access points, each of which configured to perform wireless communication with the transport vehicle, in which the control device and the transport vehicle are configured to be communicable with each other in both directions via any of the plurality of access points, and the control device transmits a command for communication recovery to the transport vehicle, as communication from the control device to the transport vehicle is valid, when communication from the transport vehicle to the control device is interrupted.

In a configuration in which the control device and the transport vehicle communicate with each other in both directions, even in a case in which communication from the transport vehicle to the control device is interrupted, communication from the control device to the transport vehicle is not necessarily impossible. According to the present configuration, in a case in which communication from the transport vehicle to the control device is interrupted, the control device transmits a command for communication recovery to the transport vehicle, as communication from the control device to the transport vehicle is valid. If the communication from the control device to the transport vehicle is valid, since the command is delivered from the control device to the transport vehicle, the transport vehicle is able to be operated for communication recovery by the command. Therefore, according to the present configuration, it is possible to maintain a favorable communication state between the control device and the transport vehicle.

Further features and advantages of the technique according to the present disclosure will be apparent from the following exemplary and non-limiting description with reference to the accompanying drawings.

### BRIEF DESCRIPTION OF THE DRAWINGS

FIG. 1 is a plan view of an article transport facility;

FIG. 2 is a control block diagram;

FIG. 3 is a conceptual diagram showing a communication configuration;

FIG. 4 is a diagram showing switching of an access point based on a point switching command;

FIG. 5 is a diagram showing movement of a transport vehicle based on a movement command;

FIG. 6 is a diagram showing a cycle in which a confirmation signal is transmitted; and

FIG. 7 is a diagram showing information stored when a communication failure vehicle is certified.

### DESCRIPTION OF THE INVENTION

Hereinafter, embodiments of an article transport facility will be described with reference to the drawings.

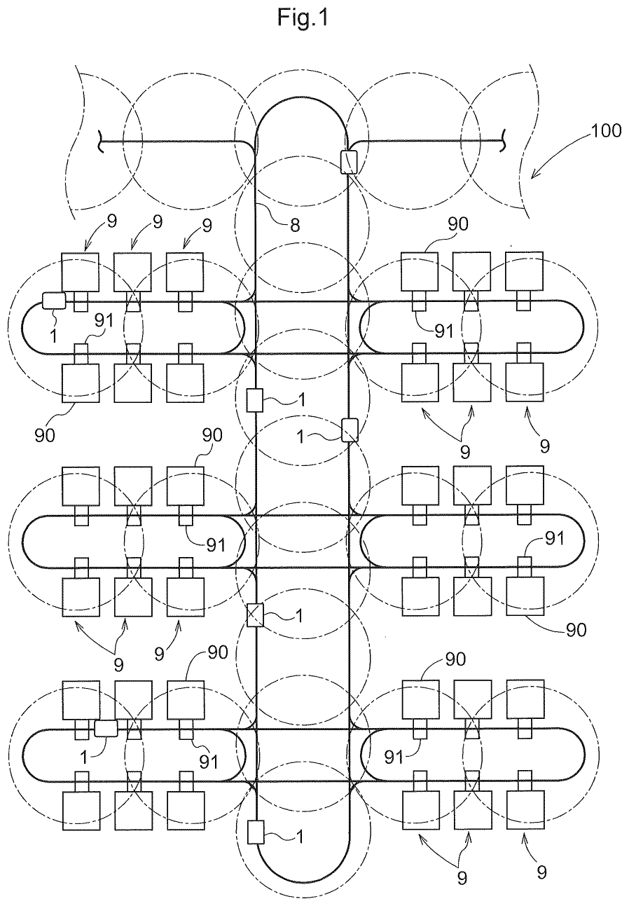

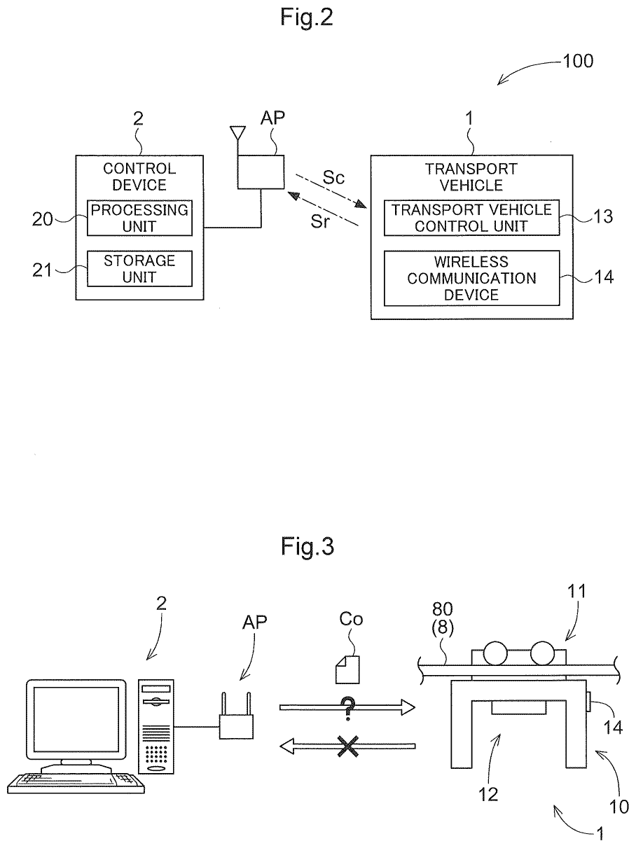

As shown in FIG. 1, an article transport facility 100 includes transport vehicles 1 that move along a prescribed path 8 to transport articles (not shown), and a control device 2 (see FIG. 2 and the like) that controls the transport vehicles 1.

As shown in FIG. 3, in the present embodiment, the path 8 is configured by using a rail 80 installed near a ceiling. The transport vehicle 1 is configured as a so-called ceiling transport vehicle that travels while being supported by the rail 80. In the present embodiment, the transport vehicle 1 includes a body 10, a traveling portion 11 that travels along the rail 80, and a holder 12 that holds the article. The body 10 is configured to be capable of accommodating the holder 12 and the article held by the holder 12.

As shown in FIG. 1, in the present embodiment, the article transport facility 100 includes a plurality of transfer target locations 9 provided along the path 8. The transfer target location 9 is disposed below the path 8. In the present example, the path 8 includes an inter-bay and a plurality of intra-bays connected to the inter-bay. The plurality of transfer target locations 9 are provided in each intra-bay. The inter-bay is able to be referred to as a movement area in which the transport vehicle 1 mainly moves. The intra-bay is able to be referred to as a transfer area in which the transport vehicle 1 mainly performs a transferring operation of the article. The transport vehicle 1 is configured to transfer the article with the transfer target locations 9 by lifting and lowering the holder 12 (see FIG. 3).

In the present embodiment, the article transport facility 100 includes a plurality of transport vehicles 1. Each of the plurality of transport vehicles 1 is configured to receive a transport command from the control device 2 (see FIG. 2 and the like) and execute a task in accordance with the transport command. For example, the transport command includes information on a transport source and a transport destination of the article. The transport vehicle 1 that receives the transport command transports the article from the transport source to the transport destination. The transport source and the transport destination include the transfer target locations 9.

The articles handled by the article transport facility 100 are various. In the present example, the article transport facility 100 is used in a semiconductor manufacturing factory. Therefore, a substrate accommodating container (so-called front opening unified pod (FOUP)) that accommodates a substrate (a wafer, a panel, or the like), a reticle accommodating container (so-called reticle pod) that accommodates a reticle, and the like are the articles. In this case, the transport vehicle 1 transports the article, such as the substrate accommodating container or the reticle accommodating container, along the path 8 between respective steps.

In the present embodiment, the transfer target location 9 includes a processing device 90 that performs processing on the article and a transfer table 91 that is disposed adjacent to the processing device 90. In the present specification, the “processing on the article” means processing on an accommodated article (substrate or reticle) accommodated in the article as the accommodating container. The transport vehicle 1 receives the article on which the processing by the processing device 90 is finished from the transfer table 91 or delivers the article on which the processing by the processing device 90 is not finished to the transfer table 91. The processing device 90 performs, for example, various processing such as thin film formation, photolithography, and etching.

As shown in FIG. 2, the article transport facility 100 includes a plurality of access points AP (only one access point AP is shown in FIG. 2) that performs wireless communication with the transport vehicle 1, respectively. The access point AP is disposed at a center of each of a plurality of circular ranges shown in FIG. 1. These circular ranges indicate a guideline of a communicable range of each access point AP. However, this is only the guideline, and communication may be possible even outside the circular range.

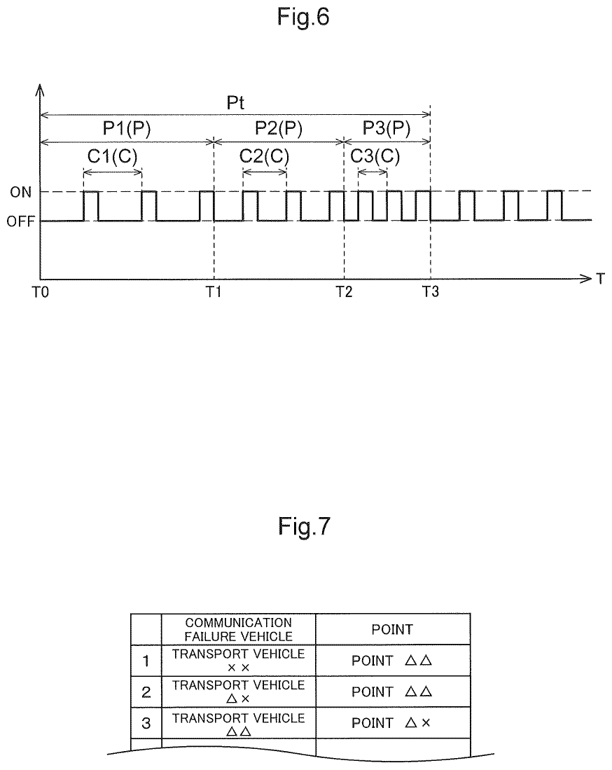

The control device 2 and the transport vehicle 1 are configured to be communicable with each other in both directions via any of the plurality of access points AP. Although details will be described later, the control device 2 is configured to repeatedly transmit a confirmation signal Sc to the transport vehicle 1 at a set cycle C (see FIG. 6). The transport vehicle 1 is configured to transmit a reception signal Sr to the control device 2 in accordance with receiving of the confirmation signal Sc. With such a configuration, the control device 2 is able to periodically confirm a communication state with the transport vehicle 1.

In the present embodiment, the control device 2 includes a processing unit 20 and a storage unit 21. The processing unit 20 is configured by using, for example, an arithmetic processing device such as a central processing unit (CPU). The storage unit 21 is configured by using, for example, a storage device such as a random access memory (RAM) or a read only memory (ROM) that is able to be referred to by an arithmetic processing device. Then, each functional unit of the control device 2 functions by software (program) stored in the storage unit 21 or hardware such as an arithmetic circuit provided separately, or both thereof. The processing unit 20 provided in the control device 2 is operated as a computer that executes each program.

In the present embodiment, the transport vehicle 1 includes a transport vehicle control unit 13 and a wireless communication device 14. The transport vehicle control unit 13 is configured by using, for example, an arithmetic processing device such as a central processing unit (CPU). The wireless communication device 14 is configured to be communicable with the control device 2. In the present example, the wireless communication device 14 is configured to communicate with each of the plurality of access points AP in a wireless manner. Moreover, each of the plurality of access points AP is configured to communicate with the control device 2 in a wired manner. That is, the wireless communication device 14 is configured to be communicable with the control device 2 through any of the plurality of access points AP.

As shown in FIG. 3, the control device 2 is connected to an operation terminal. An operator is able to input various commands to the control device 2 by operating the operation terminal, and is also able to refer to a control situation by using the operation terminal.

The access point AP is configured by using a wireless access point device. The access point AP is configured to emit wireless radio waves. A communication intensity between the access point AP and the transport vehicle 1 is represented by a received signal strength indicator (RSSI). The unit is, for example, decibel milliwatt (dBm).

As described above, in the article transport facility 100 according to the present disclosure, wireless communication by the access point AP is used for communication between the control device 2 and the transport vehicle 1. Therefore, a communication failure may occur between the transport vehicle 1 and the access point AP. Such a communication failure may occur due to an abnormality of the communication device, the surrounding environment, or the like, but it is difficult to quickly specify the cause thereof. In addition, if any of communications between the control device 2 and the transport vehicle 1 in both directions is not able to be satisfactorily performed, it may be said that there is a communication failure. That is, in a case in which the communication failure occurs, there is a case in which only the communication from the control device 2 to the transport vehicle 1 is a failure, a case in which only the communication from the transport vehicle 1 to the control device 2 is a failure, or a case in which the communication is a failure in both directions. However, it is difficult to quickly specify the details of the communication failure.

Therefore, as shown in FIG. 3, in the article transport facility 100 according to the present disclosure, in a case in which the communication from the transport vehicle 1 to the control device 2 is interrupted, the control device 2 transmits a command Co for communication recovery to the transport vehicle 1, as the communication from the control device 2 to the transport vehicle 1 is valid. To further describe, in a case in which the communication from the transport vehicle 1 to the control device 2 is interrupted, the control device 2 is not able to confirm a response from the transport vehicle 1. Therefore, the control device 2 is not able to confirm that the communication from the control device 2 to the transport vehicle 1 is valid. However, in the article transport facility 100 according to the present disclosure, the control device 2 estimates that the communication from the control device 2 to the transport vehicle 1 is valid and transmits the command Co to the transport vehicle 1. In other words, the control device 2 transmits the command Co to the transport vehicle 1 regardless of whether the communication from the control device 2 to the transport vehicle 1 is valid or invalid. As a result, in a case in which the communication from the control device 2 to the transport vehicle 1 is valid, the command Co is delivered to the transport vehicles 1, and the transport vehicle 1 executes a task in accordance with the command Co, whereby communication recovery is performed. The command Co for the communication recovery from the control device 2 to the transport vehicle 1 may be transmitted after the communication from the transport vehicles 1 to the control device 2 is interrupted. For example, the command Co may be transmitted at the same time as the communication from the transport vehicle 1 to the control device 2 is interrupted, may be transmitted immediately after the communication is interrupted, or may be transmitted after a preset period has elapsed from the interruption of the communication.

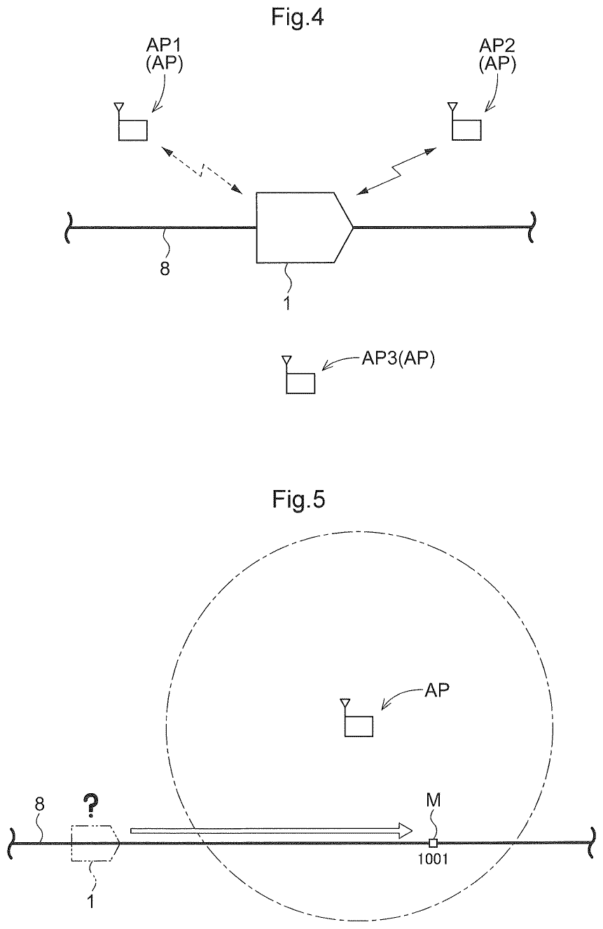

As shown in FIG. 4, in the present embodiment, the command Co transmitted by the control device 2 includes a point switching command for causing the transport vehicle 1 to switch the access point AP of the connection destination. Accordingly, it is possible to prompt the transport vehicle 1 to switch to the access point AP having a stronger communication intensity. Therefore, it is easy to recover the communication between the control device 2 and the transport vehicles 1.

In the present embodiment, in a case in which there are a plurality of access points AP that are candidates for a new connection destination, the transport vehicle 1 that has received the point switching command selects any of the plurality of access points AP and switches the connection destination to the selected access point AP. For example, the transport vehicle 1 may include a reception intensity detection unit (not shown) that detects a reception intensity of radio waves, and may select the access point AP as the connection destination based on a detection result of the reception intensity detection unit. In this case, the transport vehicle 1 may select the access point AP having the strongest reception intensity.

As in the example shown in FIG. 4, in a case of receiving the point switching command from the control device 2, the transport vehicle 1 that moves while being connected to a first access point AP1 switches the connection destination to an access point AP (second access point AP2 or third access point AP3 in the example shown in the drawing) other than the first access point AP1. In the example shown in the drawing, the transport vehicle 1 switches the connection destination from the first access point AP1 to the second access point AP2.

As shown in FIG. 5, in the present embodiment, the command Co transmitted by the control device 2 includes a movement command for moving the transport vehicle 1 from the current position. Accordingly, there is a high possibility that the transport vehicle 1 will move to a place where the communication environment is better than the current position. Therefore, it is easy to recover the communication between the control device 2 and the transport vehicles 1.

As a premise for transmitting the movement command, there is a situation that the communication from the transport vehicle 1 to the control device 2 is interrupted. Therefore, the control device 2 is not able to ascertain the current position of the transport vehicle 1. However, by transmitting the movement command from the control device 2 to the transport vehicle 1, the transport vehicle 1 moves from the current position thereof regardless of where the current position of the transport vehicle 1 is. The transport vehicle 1 that has started to move from the current position searches for a connectable access point AP and tries to connect to the searched access point AP. If the connection is successful, the communication between the control device 2 and the transport vehicles 1 is recovered. In a case in which a transfer operation of the article is performed in a state in which the transport vehicle 1 stops at the current position, the transport vehicle 1 moves from the current position after the transfer operation of the article is finished.

In the present embodiment, the movement command includes information on a movement destination to which the transport vehicle 1 is to be moved. Alternatively, the control device 2 transmits the movement command to the transport vehicle 1 and designates the movement destination to which the transport vehicle 1 is to be moved.

In the present embodiment, a plurality of information holding bodies M is installed at intervals along an extension direction of the path 8. FIG. 5 shows one information holding body M for convenience of description. Each information holding body M holds address information on a point where the information holding body M is installed. The transport vehicle 1 includes a reading device that reads address information from the information holding body M, and travels on the path 8 while reading the address information on each information holding body. For example, a one-dimensional code or a two-dimensional code is able to be used as the information holding body M, and a one-dimensional code reader or a two-dimensional code reader is able to be used as the reading device.

In the example shown in FIG. 5, the information holding body M installed at an address 1001 is set as the movement destination of the transport vehicle 1. The transport vehicle 1 that has received the movement command moves toward the address 1001. The transport vehicle 1 that has arrived at the address 1001 tries to connect to the access point AP closest thereto until arriving at the address 1001. If the connection is successful, the communication between the control device 2 and the transport vehicles 1 is recovered.

In a case in which the transfer target location 9 includes an ejectable station (ejectable location) at which the transport vehicle 1 is able to be ejected (in other words, retreated) to the transfer target location 9 and an unejectable station (unejectable location) at which the transport vehicle 1 is not able to be ejected to the transfer target location 9, the ejectable station may be set as the movement destination of the transport vehicle 1 when the movement command is issued. In addition, the transfer target location 9 may include a waitable station (waitable location) where the transport vehicle 1 is able to be waited and an unwaitable station (unwaitable location) where the transport vehicle 1 is not able to be waited. In this case, if a plurality of unwaitable stations are sequentially set as the movement destinations of the transport vehicle 1 when the movement command is issued, since the transport vehicle 1 is able to be constantly moved, the number of the access points AP that are candidates for the connection destination is able to be increased. Therefore, the number of connection retries is able to be increased, and the communication recovery between the control device 2 and the transport vehicle 1 is able to be expected. In this case, for example, a plurality of unwaitable stations may be set in a closed loop path along which the transport vehicle 1 is able to go around without stopping.

As described above, in the present embodiment, the control device 2 is configured to transmit the confirmation signal Sc to the transport vehicle 1, and the transport vehicle 1 is configured to transmit the reception signal Sr to the control device 2 in accordance with receiving of the confirmation signal Sc (see FIG. 2).

As shown in FIG. 6, in the present embodiment, the control device 2 is configured to repeatedly transmit the confirmation signal Sc to the transport vehicle 1 at a set cycle C. A horizontal axis of FIG. 6 is a time T. The control device 2 transmits the confirmation signal Sc to the transport vehicle 1 at the timing of “ON” in the drawing.

In the present embodiment, in a case in which the control device 2 does not receive the reception signal Sr from the transport vehicle 1 for a predetermined set period P, the control device 2 executes a cycle change processing of changing the set cycle C to be shorter.

In the present embodiment, a plurality of set periods P is set, and the control device 2 executes the cycle change processing each time the set period P elapses. In the example shown in FIG. 6, at least a first set period P1, a second set period P2, and a third set period P3 are set.

The control device 2 transmits the confirmation signal Sc to the transport vehicle 1 at a first set cycle C1 until the first set period P1 elapses from a time point at which the last reception signal Sr is received from the transport vehicle 1 (hereinafter, referred to as a “last reception time point T0”). The first set period P1 is, for example, 30 seconds, and the first set cycle C1 is, for example, 10 seconds. In this case, the control device 2 transmits the confirmation signal Sc three times within the first set period P1.

In a case in which the control device 2 does not receive the reception signal Sr from the transport vehicle 1 until the first set period P1 elapses from the last reception time point T0, the control device 2 executes the cycle change processing to change the set cycle C from the first set cycle C1 to a second set cycle C2. The control device 2 transmits the confirmation signal Sc to the transport vehicle 1 in the second set cycle C2 until the second set period P2 elapses from the time point T1 at which the cycle change processing of changing the set cycle C to the second set cycle C2 is executed. The second set cycle C2 is shorter than the first set cycle C1. In addition, in the present example, the second set period P2 is shorter than the first set period P1. The second set period P2 is, for example, 15 seconds, and the second set cycle C2 is, for example, 5 seconds. In this case, the control device 2 transmits the confirmation signal Sc three times within the second set period P2.

In a case in which the control device 2 does not receive the reception signal Sr from the transport vehicle 1 until the second set period P2 elapses from the time point T1 at which the cycle change processing of changing the set cycle C to the second set cycle C2 is executed, the control device 2 executes the cycle change processing again to change the set cycle C from the second set cycle C2 to the third set cycle C3. The control device 2 transmits the confirmation signal Sc to the transport vehicle 1 in the third set cycle C3 until the third set period P3 elapses from the time point T2 at which the cycle change processing of changing the set cycle C to the third set cycle C3 is executed. The third set cycle C3 is shorter than the second set cycle C2. In addition, in the present example, the third set period P3 is shorter than the second set period P2. The third set period P3 is, for example, 9 seconds, and the third set cycle C3 is, for example, 3 seconds. In this case, the control device 2 transmits the confirmation signal Sc three times within the third set period P3.

In the present embodiment, in a case in which the state in which the reception signal Sr is not received from the transport vehicle 1 is continued for a predetermined certification reference period Pt, the control device 2 certifies the transport vehicle 1 as the communication failure vehicle. A start time point of the certification reference period Pt is the last reception time point T0. In the example shown in the drawing, at time point T3, the certification reference period Pt ends, and the certification of the communication failure vehicle is performed. In the present example, the certification reference period Pt is equal to a period in which the first set period P1, the second set period P2, and the third set period P3 are added. Individual information on the transport vehicle 1 certified to be the communication failure vehicle is stored in the storage unit 21 of the control device 2. In the present example, even after the transport vehicle 1 is certified to be the communication failure vehicle, the control device 2 continues to transmit the confirmation signal Sc to the transport vehicle 1 for a predetermined period. In addition, the control device 2 may transmit an approach prohibition command indicating that an approach to the communication failure vehicle is prohibited, to another transport vehicle 1 that is not the communication failure vehicle. The transport vehicle 1 that has received the approach prohibition command is prevented from entering an area (for example, a rear area) around the communication failure vehicle, so that the transport vehicle 1 does not approach the communication failure vehicle. The approach prohibition command may be issued after the time point T3 at which the communication failure vehicle is certified. In addition, instead of the approach prohibition command, the control device 2 may prohibit a normal transport vehicle 1 other than the communication failure vehicle from entering the lane in which the communication failure vehicle travels. Alternatively, in a case in which the control device 2 selects the movement path in which the cost to the destination is minimized based on the cost (weight) of each lane, the control device 2 may increase the cost of the lane in which the communication failure vehicle travels to make it difficult to select the lane as the movement path in a case in which the movement path of the normal transport vehicle 1 other than the communication failure vehicle is determined.

As shown in FIG. 7, in the present embodiment, the control device 2 stores the information on the transport vehicle 1 certified as the communication failure vehicle and the information on the position of the transport vehicle 1 at the time of certification in association with each other. As shown in FIG. 7, the “information on the transport vehicle 1 certified as the communication failure vehicle” is individual information on the transport vehicle 1. The “information on the position of the transport vehicle 1 at the time of certification” is information on a point on the path 8.

In the present embodiment, the control device 2 stores the individual information on the transport vehicle 1 certified as the communication failure vehicle and the information on the position at which the transport vehicle 1 is estimated to be present at the time of certification in association with each other. To add description, since the control device 2 is not able to communicate with the transport vehicle 1 that is the communication failure vehicle, the control device 2 is not able to ascertain the current position of the transport vehicle 1. The position of the transport vehicle 1 at the last reception time point T0 is the last position of the transport vehicle 1 that is able to be ascertained by the control device 2 (hereinafter, referred to as a “last ascertained position”). In the present embodiment, the control device 2 estimates the position (hereinafter, referred to as an “estimated position”) of the transport vehicle 1 at the time of certification as the communication failure vehicle based on the last ascertained position of the transport vehicle 1. The control device 2 stores the individual information on the transport vehicle 1 certified as the communication failure vehicle and the information on the estimated position of the transport vehicle 1 at the time of certification by the storage unit 21 (see FIG. 2). The storage unit 21 may be provided outside the control device 2 (for example, a server capable of communicating with the control device 2).

As described above, the information stored in the storage unit 21 by the control device 2, that is, the individual information on the transport vehicle 1 certified as the communication failure vehicle and the information on the estimated position of the transport vehicle 1 at the time of certification is able to be used to specify the cause of the communication failure occurring between the control device 2 and the transport vehicle 1. For example, it is possible to ascertain whether the communication failure is based on a specific individual by using the information on the transport vehicle 1 certified to be the communication failure vehicle. In addition, for example, the information on the estimated position of the transport vehicle 1 at the time of the certification is used to ascertain whether the communication failure is based on the surrounding environment (presence of a structure that blocks radio waves or the like) or a specific access point AP (failure of the access point AP or the like).

### OTHER EMBODIMENTS

Next, other embodiments will be described.

(1) In the embodiment described above, the example is described in which the control device 2 stores the information on the transport vehicle 1 certified as the communication failure vehicle and the information on the position of the transport vehicle 1 at the time of certification in association with each other. However, the present invention is not limited to such an example, and the control device 2 may calculate an area from the position (last ascertained position) of the transport vehicle 1 at the last reception time point T0 to the position (estimated position) of the transport vehicle 1 estimated to be present at the time point T3 when the transport vehicle 1 is certified to be the communication failure vehicle, and store information on the area and the information on the transport vehicle 1 certified to be the communication failure vehicle in association with each other.

(2) In the embodiment described above, the example is described in which, in a case in which there are a plurality of access points AP as candidates for a new connection destination, the transport vehicle 1 that has received the point switching command selects any of the plurality of access points AP and switches the connection destination to the selected access point AP. However, the present invention is not limited to such a configuration. In a case in which there are a plurality of access points AP that are candidates for a new connection destination, the transport vehicle 1 may be configured to try to connect to each access point AP without giving priority as the connection destination to the plurality of access points AP. In this case, the transport vehicle 1 may maintain a connection state with the access point AP that is first connected. Accordingly, it is possible to expect early communication recovery between the control device 2 and the transport vehicle 1.

(3) In the embodiment described above, the example is described in which the plurality of set periods P serving as the reference for the control device 2 to execute the cycle change processing are set. However, the present invention is not limited to such an example, and a single set period P may be set.

(4) In embodiment described above, the example has been described in which the first set period P1, the second set period P2, and the third set period P3 are set to gradually decrease in the order of description. However, the present invention is not limited to such an example, and for example, the second set period P2 and the third set period P3 may be set to the same length.

(5) In the embodiment described above, the example is described in which each of the plurality of access points AP is configured to communicate with the control device 2 in a wired manner. However, the present invention is not limited to such an example, and at least some of the plurality of access points AP may be configured to communicate with the control device 2 wirelessly.

(6) In the embodiment described above, the example is described in which the path 8 is configured by using the rail 80 installed near the ceiling, and the transport vehicle 1 is configured as the ceiling transport vehicle that travels while being supported by the rail 80. However, the present invention is not limited to such an example, and the transport vehicle 1 may be configured as a floor surface transport vehicle that travels on a floor surface. In this case, the path 8 may be configured by using a magnetic tape or the like provided along the floor surface, or may be virtually set along the floor surface.

(7) In addition, the configuration disclosed in the embodiment described above is able to be applied in combination with configurations disclosed in other embodiments as long as there is no contradiction. The embodiments disclosed in the present specification are merely exemplary in all respects with regard to other configurations. Therefore, various modifications are able to be made within a range not departing from the scope of the present disclosure.

### Summary of Present Embodiment

A summary of the present embodiment will be described below.

An article transport facility including a transport vehicle configured to move along a prescribed path to transport an article; a control device configured to control the transport vehicle; and a plurality of access points, each of which configured to perform wireless communication with the transport vehicle, in which the control device and the transport vehicle are configured to be communicable with each other in both directions via any of the plurality of access points, and the control device transmits a command for communication recovery to the transport vehicle, as communication from the control device to the transport vehicle is valid, when communication from the transport vehicle to the control device is interrupted.

In a configuration in which the control device and the transport vehicle communicate with each other in both directions, even in a case in which communication from the transport vehicle to the control device is interrupted, communication from the control device to the transport vehicle is not necessarily impossible. According to the present configuration, in a case in which communication from the transport vehicle to the control device is interrupted, the control device transmits a command for communication recovery to the transport vehicle, as communication from the control device to the transport vehicle is valid. If the communication from the control device to the transport vehicle is valid, since the command is delivered from the control device to the transport vehicle, the transport vehicle is able to be operated for communication recovery by the command. Therefore, according to the present configuration, it is possible to maintain a favorable communication state between the control device and the transport vehicle.

It is preferable that the command includes a point switching command that causes the transport vehicle to switch the access point of the connection destination.

According to the present configuration, it is possible to cause the transport vehicle to switch the access point of the connection destination. Accordingly, the transport vehicle is prompted to switch to the access point having a stronger communication intensity, and thus it is easy to recover communication with the control device.

It is preferable that the command includes a movement command for moving the transport vehicle from the current position.

According to the present configuration, it is possible to move the transport vehicle from the current position. Accordingly, a possibility that the transport vehicle is moved to a place where the communication environment is better than the current position is increased, and thus it is easy to recover the communication with the control device.

It is preferable that the control device is configured to repeatedly transmit the confirmation signal to the transport vehicle at a set cycle, the transport vehicle is configured to transmit the reception signal to the control device in accordance with receiving of the confirmation signal, and the control device executes cycle change processing of changing the set cycle to be shorter in a case in which the control device does not receive the reception signal from the transport vehicle within a predetermined set period.

According to the present configuration, the control device is able to periodically confirm the communication state with the transport vehicle. In a case in which there is no response (transmission of the reception signal) from the transport vehicle within the set period, many response opportunities of the transport vehicle are able to be secured by increasing the frequency of transmission of the confirmation signal. In addition, by increasing the frequency of transmission of the confirmation signal, the control device is able to easily recognize that the communication is recovered in a case in which the communication is recovered. Therefore, the control device is able to transmit the transport command to the transport vehicle at an early stage, and as a result, the transport efficiency of the entire facility is improved.

It is preferable that the control device certifies the transport vehicle as the communication failure vehicle in a case in which a state in which the control device does not receive the reception signal from the transport vehicle continues for a predetermined certification reference period, and the control device stores information on the transport vehicle certified as the communication failure vehicle and information on the position of the transport vehicle at a time of certification in association with each other.

According to the present configuration, it is easy to specify a cause of a communication failure that occurs between the control device and the transport vehicle. For example, it is possible to ascertain whether the communication failure is based on a specific individual by using the information on the transport vehicle certified as the communication failure vehicle. In addition, for example, by using the information on the position of the transport vehicle at the time of the certification, it is possible to ascertain whether the communication failure is based on the surrounding environment or a specific access point.

### INDUSTRIAL APPLICABILITY

The technique according to the present disclosure is able to be used for an article transport facility including transport vehicles that move along a prescribed path to transport articles, a control device that controls the transport vehicle, and a plurality of access points that performs wireless communication with the transport vehicle, respectively.

What is claimed is:

1. An article transport facility, comprising:
a transport vehicle configured to move along a prescribed path to transport an article;
a control device configured to control the transport vehicle; and
a plurality of access points, each of which configured to perform wireless communication with the transport vehicle,
wherein the control device and the transport vehicle are configured to be communicable with each other in both directions via any of the plurality of access points, and
wherein the control device transmits a command for communication recovery to the transport vehicle, as communication from the control device to the transport vehicle is valid, when communication from the transport vehicle to the control device is interrupted.

2. The article transport facility according to claim 1, wherein the command comprises a point switching command for causing the transport vehicle to switch the access points of connection destinations.

3. The article transport facility according to claim 1, wherein the command comprises a movement command for moving the transport vehicle from a current position.

4. The article transport facility according to claim 1, wherein:
the control device is configured to repeatedly transmit a confirmation signal to the transport vehicle at a set cycle,
the transport vehicle is configured to transmit a reception signal to the control device in accordance with receiving of the confirmation signal, and
the control device executes cycle change processing of changing the set cycle to be shorter when the control device does not receive the reception signal from the transport vehicle within a predetermined set period.

5. The article transport facility according to claim 4, wherein the control device certifies the transport vehicle as a communication failure vehicle when a state in which the control device does not receive the reception signal from the transport vehicle continues for a predetermined certification reference period, and
wherein the control device stores information on the transport vehicle certified as the communication failure vehicle and information on a position of the transport vehicle at a time of certification in association with each other.

6. The article transport facility according to claim 2, wherein:
the control device is configured to repeatedly transmit a confirmation signal to the transport vehicle at a set cycle,
the transport vehicle is configured to transmit a reception signal to the control device in accordance with receiving of the confirmation signal, and
the control device executes cycle change processing of changing the set cycle to be shorter when the control device does not receive the reception signal from the transport vehicle within a predetermined set period.

7. The article transport facility according to claim 3, wherein:
the control device is configured to repeatedly transmit a confirmation signal to the transport vehicle at a set cycle,
the transport vehicle is configured to transmit a reception signal to the control device in accordance with receiving of the confirmation signal, and
the control device executes cycle change processing of changing the set cycle to be shorter when the control device does not receive the reception signal from the transport vehicle within a predetermined set period.
